(19) United States
(12) Patent Application Publication
(10) Pub. No.: US 2006/0049516 A1
(43) Pub. Date: Mar. 9, 2006

(54) Nickel/gold pad structure of semiconductor package and fabrication method thereof

(75) Inventors: Yu-Po Wang, Taichung Hsien (TW); Chiang-Cheng Chang, Taichung (TW); Chien-Te Chen, Taichung Hsien (TW)

Correspondence Address: EDWARDS & ANGELL, LLP, P.O. BOX 55874, BOSTON, MA, 02205, US

(73) Assignee: Siliconware Precision Industries Co., Ltd., Taichung Hsien (TW)

(21) Appl. No.: 11/145,318

(22) Filed: Jun. 3, 2005

(30) Foreign Application Priority Data
Sep. 7, 2004 (TW) 093126966

(51) Int. Cl. H01L 23/48

(52) U.S. Cl. 257/734

(57) ABSTRACT

A nickel/gold (Ni/Au) pad structure of a semiconductor package and a fabrication method thereof are provided. The fabrication method includes preparing a core layer; forming a conductive trace layer on the core layer; patterning the conductive trace layer to form at least one pad of the conductive trace layer; applying a conductive layer; forming a photoresist layer to define a predetermined plating region on the pad, wherein the predetermined plating region is smaller in area than the pad; forming a Ni/Au layer on the predetermined plating region; removing the photoresist layer and etching away the conductive layer; and applying a solder mask layer and forming at least one opening in the solder mask layer to expose the pad, wherein the opening is larger in area than the Ni/Au layer. The Ni/Au pad structure fabricated by the above method can prevent a solder extrusion effect incurred in the conventional technology.

### FIELD OF THE INVENTION

The present invention relates to nickel/gold (Ni/Au) pads of semiconductor packages and fabrication methods thereof, and more particularly, to a Ni/Au pad used as a ball pad or passive pad for a semiconductor package, and a method of fabricating the Ni/Au pad.

### BACKGROUND OF THE INVENTION

In regard to ball grid array (BGA) semiconductor package using a substrate as a chip carrier, the signal transmission design thereof generally allows signals from a chip to be transmitted to bond fingers of the substrate and then through conductive vias of the substrate to ball pads formed on a bottom surface of the substrate to be out of the semiconductor package. Alternatively, it can be designed to utilize a circuit layout on the substrate to dispose passive components on passive pads of the substrate so as to enhance the electrical performance of the semiconductor package.

A fabrication method of the above structures for the semiconductor package is disclosed in U.S. Pat. No. 6,576,540. Firstly, as shown in FIG. 1A, a conductive trace layer 51 is formed on a core layer 50 of the substrate. Then, the conductive trace layer 51 is patterned to define the location of ball pad or passive pad 52 as shown in FIG. 1B. Subsequently, as shown in FIG. 1C, a solder mask layer 53 is applied over the conductive trace layer 51, wherein at least one opening 54 is formed on the solder mask layer 53 to expose the ball pad or passive pad 52. Finally, an electroplating process is performed to form a Ni/Au layer 55 on an area of the pad 52 exposed via the opening 54 of the solder mask layer 53, as shown in FIG. 1D. This refers to a conventional Ni/Au pad structure and a fabrication method thereof. Such Ni/Au pad structure is characterized in that only the area of the pad 52 exposed via the opening 54 of the solder mask layer 53 is plated with the Ni/Au layer 55.

However, the above conventional fabrication method has a drawback that a surface of the substrate must be additionally formed with a plurality of plating circuits to carry out the electroplating process of the Ni/Au layer. Such substrate is considered not having sufficient surface area for use as a high-density substrate. Moreover, for high-frequency products, the provision of plating circuits would cause an antenna effect and generate noise, thereby adversely interfering with the signal transmission. As a result, this type of Ni/Au pad structure has now gradually lost popularity.

Accordingly, two types of methods for fabricating a Ni/Au pad without the need of plating circuits have been proposed, including a selected gold (SG) plating method and a non-plating line (NPL) Ni/Au plating method, which are described in detail as follows for the procedural steps thereof and the structures formed thereby.

With respect to the SG method, as shown in FIG. 2A, the first step is to form a conductive trace layer 51 on a substrate core layer 50. Then, as shown in FIG. 2B, a photoresist layer 60 is applied over the conductive trace layer 51 and is formed with at least one opening 61 to define the location of ball pad or passive pad on the conductive trace layer 51. As shown in FIG. 2C, a Ni/Au layer 55 is plated in the opening 61 of the photoresist layer 60, wherein the area of the Ni/Au layer 55 is equal to the area of the opening 61 of the photoresist layer 60. Subsequently, as shown in FIG. 2D, the photoresist layer 60 is removed. As shown in FIG. 2E, the conductive trace layer 51 is patterned and is applied with a solder mask layer 53 thereon, wherein at least one opening 54 is formed in the solder mask layer 53 to expose the ball pad or passive pad 52 plated with Ni/Au layer 55, and the area of the opening 54 of the solder mask layer 53 is slightly smaller than the area of the Ni/Au layer 55. The final Ni/Au pad structure fabricated by the SG method is shown in FIG. 2E.

For the NPL method, as shown in FIG. 3A, the first step is to form a conductive trace layer 51 on a substrate core layer 50. Then, as shown in FIG. 3B, a conventional exposure/development process is performed to pattern the conductive trace layer 51 and define the location of ball pad or passive pad 52. As shown in FIG. 3C, an electrolessly plated conductive layer 65 such as a conductive copper layer is deposited on the ball pad or passive pad 52 and the substrate core layer 50. Subsequently, as shown in FIG. 3D, a photoresist layer 60 is applied on the conductive layer 65 and is formed with at least one opening 61 to define an area of the ball pad or passive pad 52 to be plated with a Ni/Au layer. As shown in FIG. 3E, the Ni/Au layer 55 is plated on the area of the ball pad or passive pad 52. As shown in FIG. 3F, the photoresist layer 60 is removed and the conductive layer 65 outside of Ni/Au layer is etched away. Finally, as shown in FIG. 3G, a solder mask layer 53 is applied and is formed with at least one opening 54 for exposing the Ni/Au layer 55 on the pad 52. The final Ni/Au pad structure formed by the NPL method is shown in FIG. 3G. No matter the SG or NPL process is selected, due to an alignment error of ±75 μm of the opening 54 of the solder mask layer 53 and a resolution error of about ±50 μm of the solder mask layer 53, the area of the Ni/Au layer 55 should be slightly larger than the area of the opening 54 of the solder mask layer by a region L of approximately 125 μm (75 μm+50 μm) as shown in FIG. 3G.

The foregoing two methods can avoid the design of plating circuits and indeed improve the electrical performance. However, for the Ni/Au pad structures (as shown in FIGS. 2E and 3G) fabricated by the two methods possess a material concern makes another quality issue. This is because adhesion between the solder mask layer and the Ni/Au layer is not good, such that when a solder material 70 is formed on the pad and subjected to a reflow process, the solder material 70 due to its volumetric expansion would flow into a contact interface between the solder mask layer 53 and the Ni/Au layer 55, thereby causing a solder extrusion effect as shown in FIGS. 4 and 5. The solder extrusion effect may further cause the solder material 70 flowing into the conductive trace layer and make adjacent conductive traces 72 become bridged, thereby leading to a short-circuiting problem. FIGS. 4 and 5 respectively illustrate the solder extrusion effect of the Ni/Au pad structures formed by the SG method and the NPL method, wherein for example the Ni/Au pad serves as a passive pad for a passive component 71.

Therefore, the problem to be solved here is to develop a fabrication method of a Ni/Au pad structure on a package substrate, which can satisfy all requirements on electrical performance and is suitably applied to a high-level package product.

### SUMMARY OF THE INVENTION

In light of the foregoing drawbacks in the conventional technology, a primary objective of the present invention is to provide a Ni/Au pad structure of a semiconductor package and a fabrication method thereof, which can prevent a solder extrusion effect.

Another objective of the present invention is to provide a Ni/Au pad structure of a semiconductor package and a fabrication method thereof, which can avoid a short-circuiting problem.

Still another objective of the present invention is to provide a Ni/Au pad structure of a semiconductor package and a fabrication method thereof, which can satisfy requirements on electrical performance for high-frequency products.

In order to achieve the foregoing and other objectives, the present invention proposes a fabrication method of a Ni/Au pad structure of a semiconductor package, comprising the steps of: preparing a core layer; forming a conductive trace layer on the core layer; forming a photoresist layer to define a predetermined plating region on the conductive trace layer; forming a Ni/Au layer on the predetermined plating region; removing the photoresist layer; patterning the conductive trace layer to form a pad at a position of the Ni/Au layer wherein an area of the pad is larger than an area of the Ni/Au layer; and applying a solder mask layer and forming an opening in the solder mask layer to expose the pad, wherein an area of the opening is larger than the area of the Ni/Au layer.

The present invention also proposes another fabrication method of a Ni/Au pad structure of a semiconductor package, comprising the steps of: preparing a core layer; forming a conductive trace layer on the core layer; patterning the conductive trace layer to form a pad of the conductive trace layer; applying a conductive layer; forming a photoresist layer to define a predetermined plating region on the pad, wherein an area of the predetermined plating region is smaller than an area of the pad; forming a Ni/Au layer on the predetermined plating region; removing the photoresist layer and etching away the conductive layer; and applying a solder mask layer and forming an opening in the solder mask layer to expose the pad, wherein an area of the opening is larger than an area of the Ni/Au layer.

Accordingly, a Ni/Au pad structure fabricated by the foregoing methods comprises: a pad formed on a surface of a core layer, wherein a surface of the pad opposed to the surface of the core layer is a connecting surface; a Ni/Ai layer formed on the connecting surface of the pad, wherein an area of the Ni/Au layer is smaller than an area of the connecting surface of the pad; and a solder mask layer applied around the pad and formed with an opening for exposing the pad, wherein an area of the opening is larger than the area of the Ni/Au layer.

Therefore, compared to the conventional SG and NPL methods, the present invention is advantageous to control an area relationship between the pad, the Ni/Au layer and the opening of the solder mask layer to ensure that the Ni/Au layer is not in contact with the solder mask layer, such that a solder extrusion effect at a contact interface between a Ni/Au layer and solder mask in the conventional technology can be prevented, thereby improving the electrical performance of the semiconductor package.

### BRIEF DESCRIPTION OF THE DRAWINGS

The present invention can be more fully understood by reading the following detailed description of the preferred embodiments, with reference made to the accompanying drawings, wherein:

FIGS. 1A to 1D (PRIOR ART) are schematic diagrams showing a flowchart of a conventional fabrication method of a Ni/Au pad structure;

FIGS. 2A to 2E (PRIOR ART) are schematic diagrams showing a flowchart of a conventional SG method;

FIGS. 3A to 3G (PRIOR ART) are schematic diagrams showing a flowchart of a conventional NPL method;

FIG. 4 (PRIOR ART) is a schematic diagram showing a solder extrusion effect incurred in a structure formed by the SG method;

FIG. 5 (PRIOR ART) is a schematic diagram showing the solder extrusion effect incurred in a structure formed by the NPL method;

FIGS. 6A to 6H are schematic diagrams showing a flowchart of a fabrication method of a Ni/Au pad structure in accordance with a first preferred embodiment of the present invention;

FIG. 6I is a schematic diagram showing a Ni/Au pad structure in accordance with a second preferred embodiment of the present invention;

FIGS. 7A to 7I are schematic diagrams showing a flowchart of a fabrication method of a Ni/Au pad structure in accordance with a third preferred embodiment of the present invention; and

FIG. 8 is a schematic diagram showing a passive component mounted on the Ni/Au pad structure in accordance with the present invention.

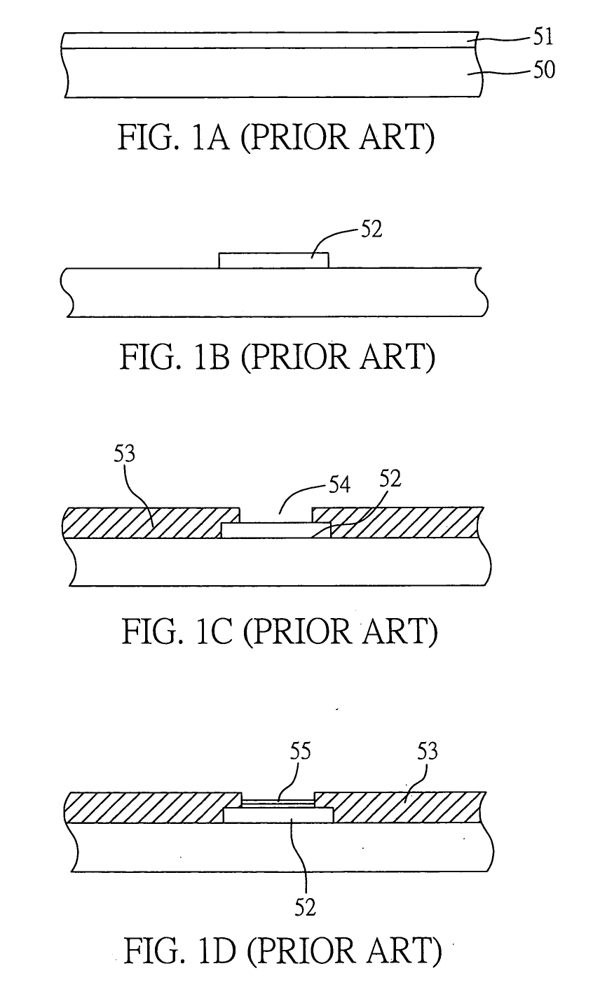

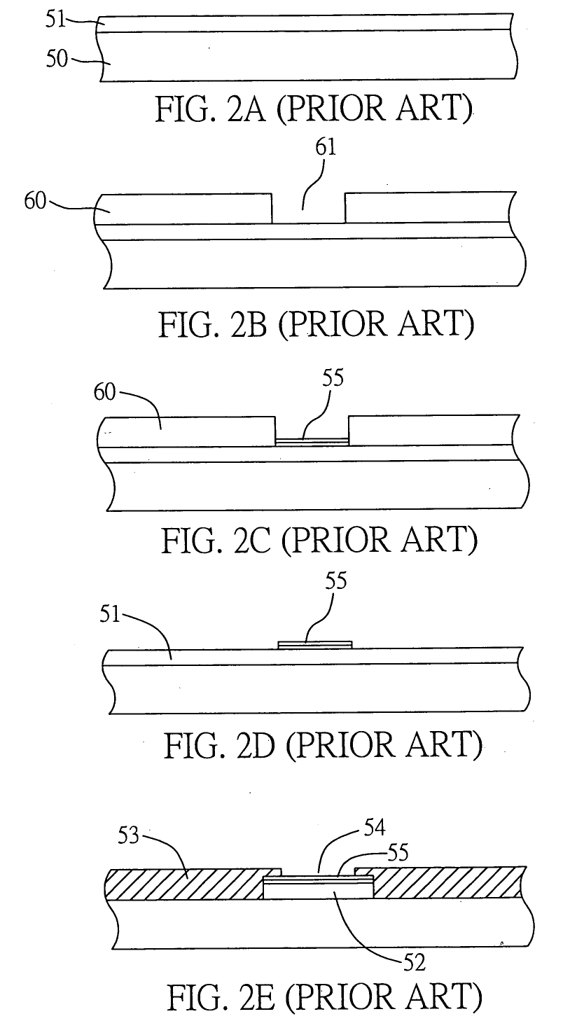

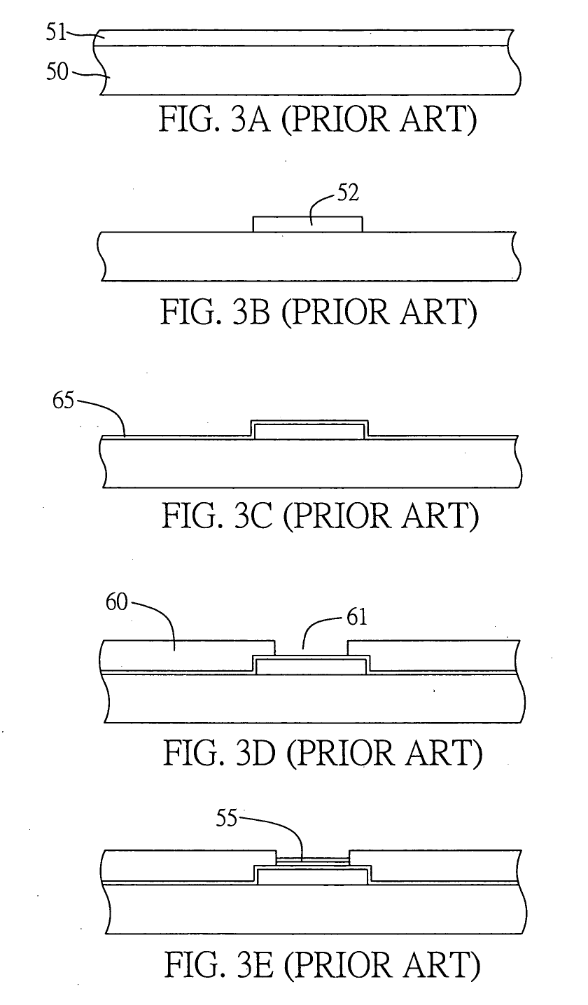

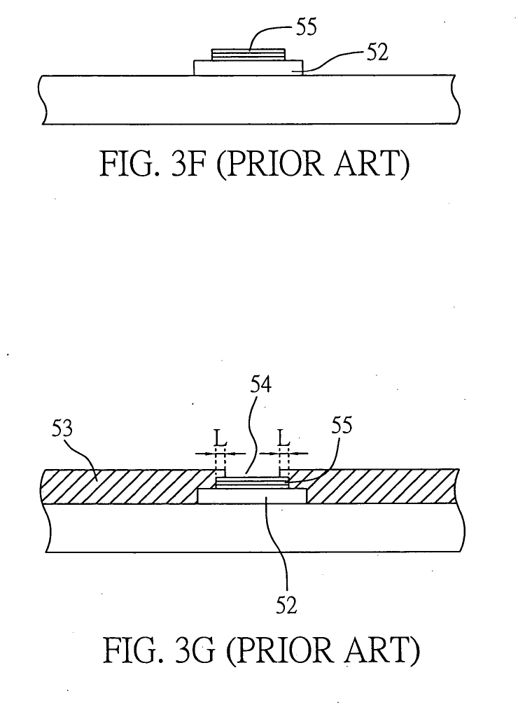

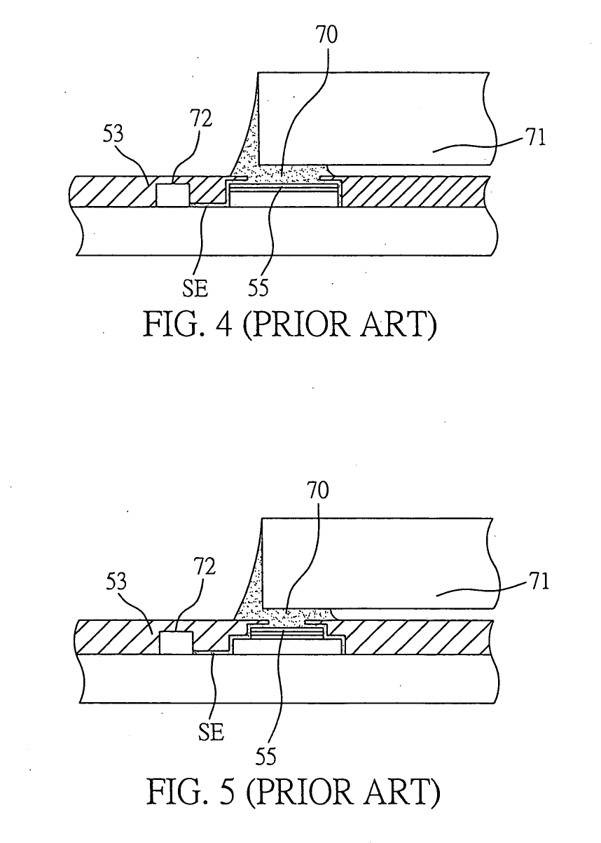

### DETAILED DESCRIPTION OF THE PREFERRED EMBODIMENTS

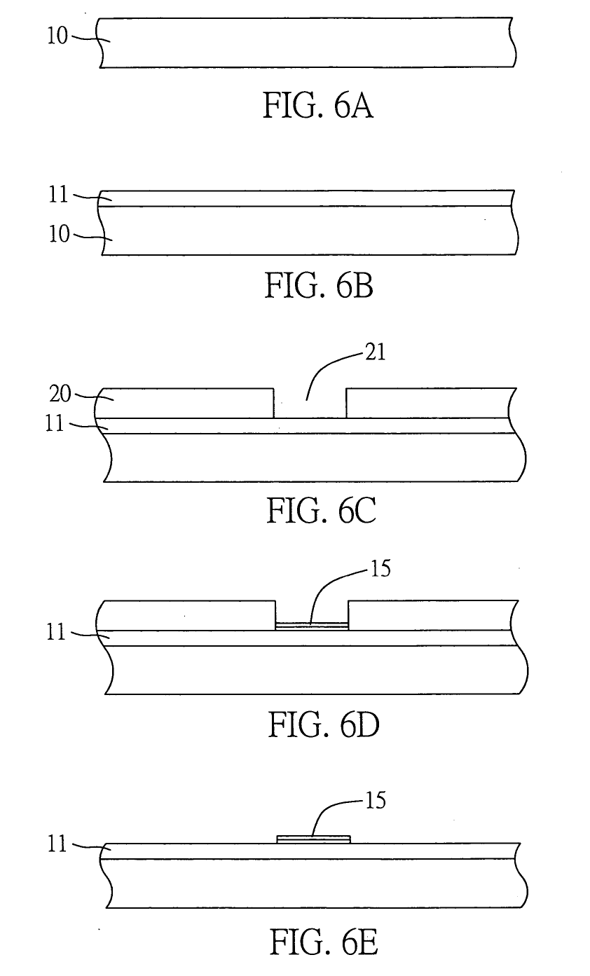

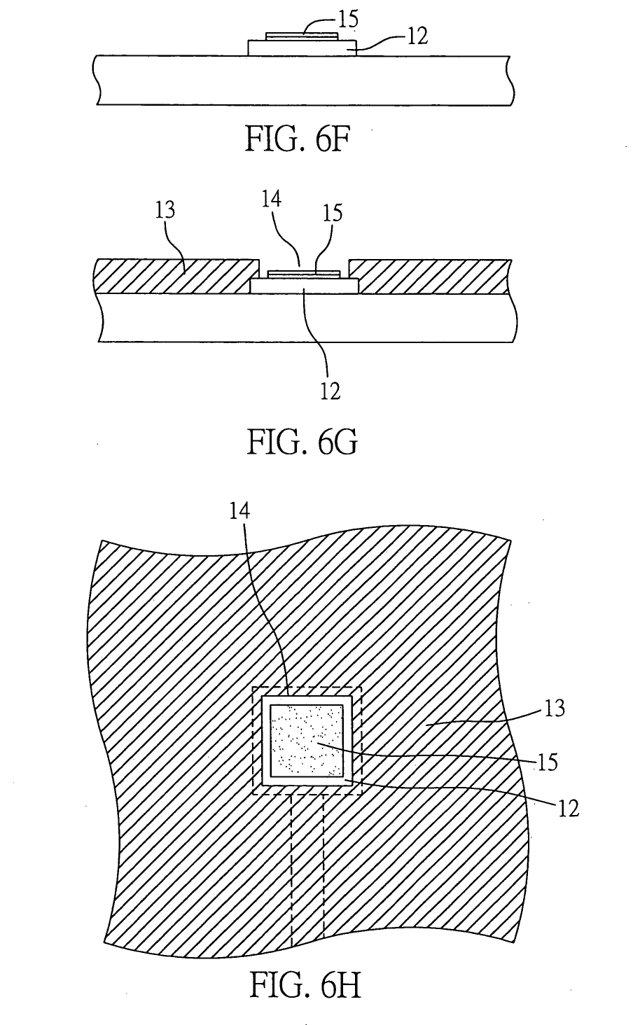

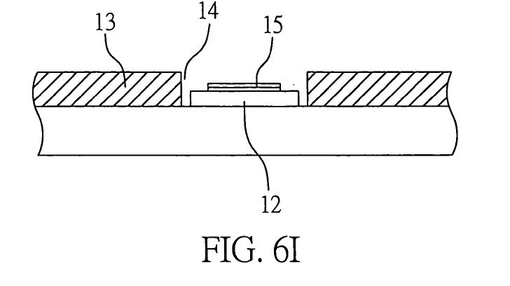

Preferred embodiments of a Ni/Au pad structure of a semiconductor package and a fabrication method thereof proposed in the present invention are described as follows with reference to FIGS. 6 to 8.

A characteristic feature of the present invention is to control an area relationship between a pad, a Ni/Au layer and a solder mask layer to ensure that the Ni/Au layer is not in contact with the solder mask layer, such that a solder extrusion effect in the conventional technology can be prevented.

In response to drawbacks of the conventional SG method, the present invention proposes a fabrication method of a Ni/Au pad structure in accordance with a first preferred embodiment with reference to FIGS. 6A to 6H. Firstly, as shown in FIG. 6A, a core layer 10 made of a resin material is prepared, wherein a plurality of conductive vias (not shown) are formed for electrically interconnecting upper and lower surfaces of the core layer 10. Then, as shown in FIG. 6B, a conductive trace layer 11 made of a copper material is formed on at least one surface of the core layer 10 (only one surface of the core layer 10 is shown in the following drawings). As shown in FIG. 6C, according to a predetermined design, a photoresist layer 20 is applied and is formed with at least one opening 21 to define a predetermined plating region on the conductive trace layer 11. As shown in FIG. 6D, a Ni/Au layer 11 is plated on the predetermined plating region.

As shown in FIG. 6E, the photoresist layer 20 is removed. Subsequently, as shown in FIG. 6F, a conventional exposure/development process is performed to pattern the conductive trace layer 11 to form a plurality of conductive traces (not shown) and at least one pad 12 at a terminal of the conductive traces according to a predetermined circuit layout, wherein the Ni/Au layer 15 is located at a central portion of the pad 12, and an area of the pad 12 is larger than an area of the Ni/Au layer 15. Finally, as shown in FIG. 6G, a solder mask layer 13 is applied over the conductive trace layer 11, and is formed with at least one opening 14 for exposing the pad 12, wherein an area of the opening 14 is slightly smaller than the area of the pad 12 but larger than the area of the Ni/Au layer 15 in this embodiment. As shown in a top view of FIG. 6H, edges of the square opening 14 of the solder mask layer 13 are spaced apart from the Ni/Au layer 15 by a distance to ensure that the solder mask layer 13 is not in contact with the Ni/Au layer 15, such that a solder extrusion effect due to poor adhesion at a contact interface between solder mask and a Ni/Au layer in the conventional technology can be prevented.

FIG. 6I shows a Ni/Au pad structure according to a second preferred embodiment of the present invention, wherein the solder mask layer 13 is formed with at least one opening 14 for exposing the pad 12, and an area of the opening 14 can be substantially equal to or larger than the area of the pad 12. Further as shown in FIG. 6I, edges of the square opening 14 of the solder mask layer 13 are spaced apart from the Ni/Au layer 15 by a distance to ensure that the solder mask layer 13 is not in contact with the Ni/Au layer 15, such that the solder extrusion effect due to poor adhesion at a contact interface between solder mask and a Ni/Au layer in the conventional technology can be prevented.

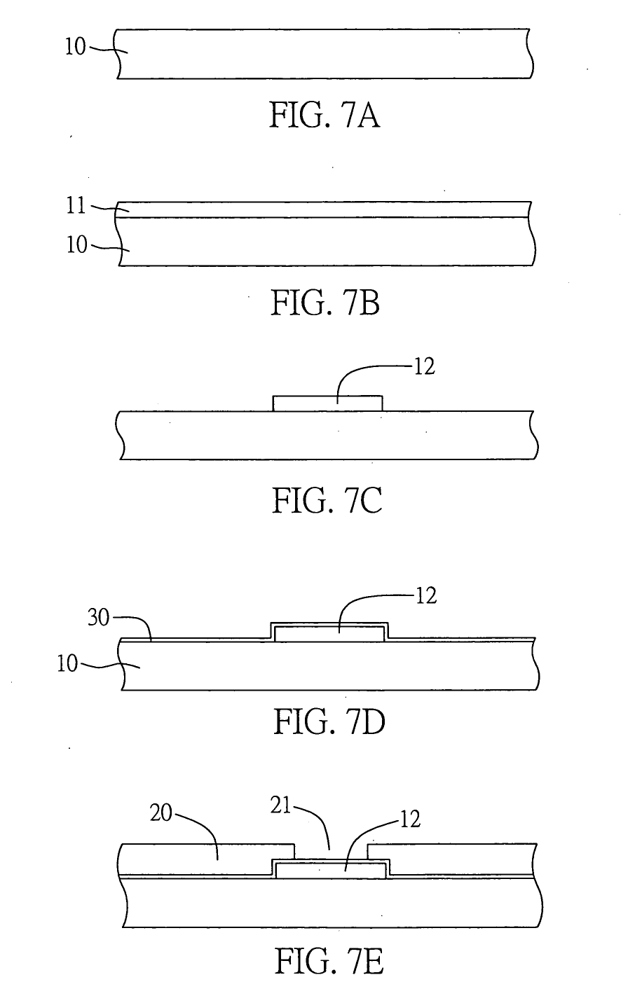

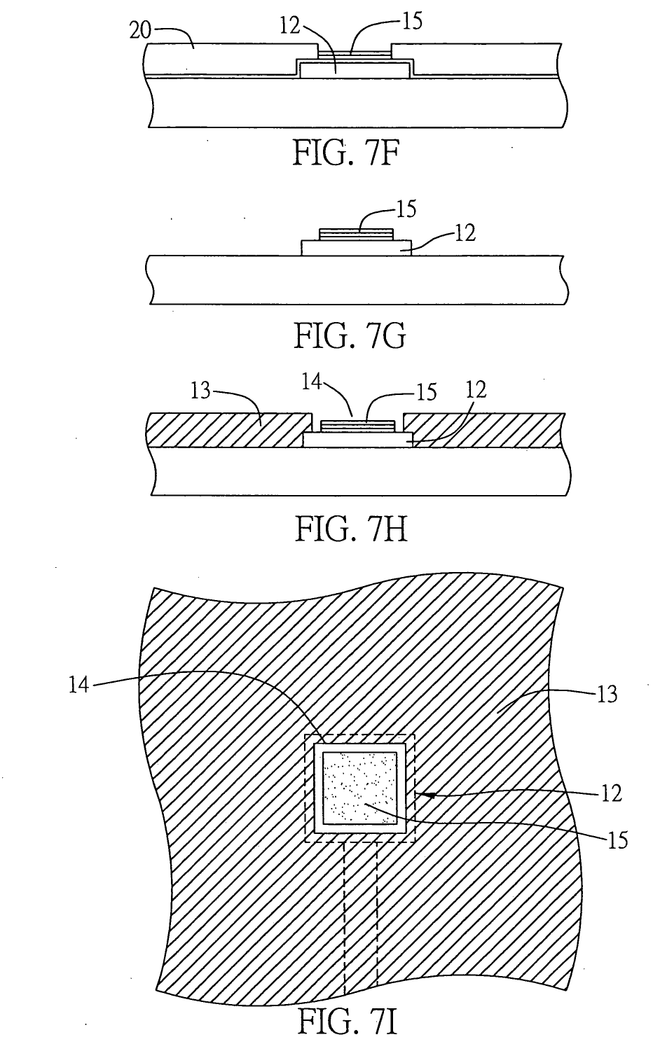

In response to drawbacks of the conventional NPL method, the present invention proposes another fabrication method of a Ni/Au pad in accordance with a third preferred embodiment with reference to FIGS. 7A to 7I. Firstly, as shown in FIG. 7A, a core layer 10 made of a resin material is prepared, wherein a plurality of conductive vias (not shown) are formed for electrically interconnecting upper and lower surfaces of the core layer 10. Then, as shown in FIG. 7B, a conductive trace layer 11 made of a copper material is formed on at least one surface of the core layer 10 (only one surface of the core layer 10 is shown in the following drawings). As shown in FIG. 7C, the conventional exposure/development process is performed to pattern the conductive trace layer 11 to form a plurality of conductive traces (not shown) and at least one pad 12 at a terminal of the conductive traces. Subsequently, as shown in FIG. 7D, an electrolessly plated conductive layer 30 such as a conductive copper layer is applied on the conductive trace layer 11, the pad 12 and a portion of the core layer 10. Besides a copper material, the conductive layer 30 can also be made of a material such as tin (Sn), chromium (Cr), palladium (Pd), nickel (Ni), tin/lead (Sn/Pb), or an alloy thereof. As shown in FIG. 7E, a photoresist layer 20 is applied and is formed with at least one opening 21 to define a predetermined plating region on the pad 12, wherein an area of the predetermined plating region is smaller than an area of the pad 12. As shown in FIG. 7F, a Ni/Au layer 15 is formed on the predetermined plating region to completely cover the predefining plating region, such that an area of the Ni/Au layer 15 is smaller than the area of the pad 12.

Subsequently, as shown in FIG. 7G, the photoresist layer 20 is removed and the conductive layer 30 is etched away. Finally, as shown in FIG. 7H, a solder mask layer 13 is applied over the conductive trace layer 11 and is formed with at least one opening 14 for exposing the pad 12, wherein an area of the opening 14 is slightly smaller than the area of the pad 12 but larger than the area of the Ni/Au layer 15. As shown in a top view of FIG. 7I, edges of the square opening 14 of the solder mask layer 13 are spaced apart from the Ni/Au layer 15 by a distance to ensure that the Ni/Au layer 15 is not in contact with the solder mask layer 13, such that the solder extrusion effect due to poor adhesion at a contact interface between solder mask and a Ni/Au layer in the conventional technology can be prevented.

Similarly to the second embodiment, the area of the opening 14 can be alternatively made substantially equal to or larger than the area of the pad 12. Such arrangement can still space the Ni/Au layer 15 from the edges of the square opening 14 of the solder mask layer 13 by a distance to ensure that the Ni/Au layer 15 is not in contact with the solder mask layer 13, such that the solder extrusion effect due to poor adhesion at a contact interface between solder mask and a Ni/Au layer in the conventional technology can be prevented.

The Ni/Au pad structure in the present invention fabricated by the foregoing two fabrication methods is respectively shown in FIGS. 6G and 7H. The Ni/Au pad structure is formed on the core layer 10 of a substrate, and comprises: a pad 12 formed on a surface of the core layer 10, wherein a surface of the pad 12 opposed to the surface of the core layer 10 is a connecting surface; a Ni/Au layer 15 formed the connecting surface, wherein an area of the Ni/Au layer 15 is smaller than an area of the connecting surface of the pad 12; and a solder mask layer 13 applied around the pad 12 and formed with an opening 14 for exposing the pad 12, wherein an area of the opening 14 is larger than the area of the Ni/Au layer 15.

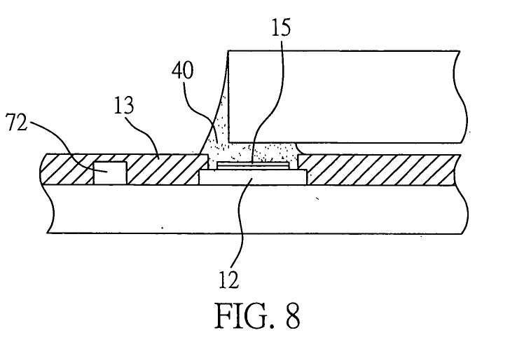

Therefore, in the use of the Ni/Au pad structure according to the present invention, for example serving as a passive pad, when a solder material 40 is formed on the Ni/Au pad structure to mount a passive component thereon, as shown in FIG. 8, the solder mask layer 13 is only in contact with the pad 12 made of the copper material (but not in contact with the Ni/Au layer 15). Due to good adhesion between the solder mask layer 13 and the copper pad 12, the solder material 40 is prevented from flowing into a contact interface between the solder mask layer 13 and the pad 12, thereby not causing bridging or short-circuiting of conductive traces 72. Moreover, since the copper material of the pad 12 has poorer wettability to the solder material 40 than to the Ni/Au layer 15, the melted solder material 40 would concentrate its movement on the surface of the Ni/Au layer 15 and is less likely to flow to the copper pad 12 around the Ni/Au layer 15, thereby further preventing the possibility of a solder extrusion effect of the solder material 40.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A nickel/gold (Ni/Au) pad structure of a semiconductor package, formed on a core layer of a substrate, the Ni/Au pad structure comprising:
a pad formed on a surface of the core layer wherein a surface of the pad opposed to the surface of the core layer is a connecting surface;
a Ni/Au layer formed on the connecting surface of the pad wherein an area of the Ni/Au layer is smaller than an area of the connecting surface of the pad; and
a solder mask layer applied around the pad and formed with an opening for exposing the pad, wherein an area of the opening is larger than the area of the Ni/Au layer.

2. The Ni/Au pad structure of claim 1, wherein the area of the opening is equal to the area of the pad.

3. The Ni/Au pad structure of claim 1, wherein the area of the opening is smaller than the area of the pad.

4. The Ni/Au pad structure of claim 1, wherein the area of the opening is larger than the area of the pad.

5. The Ni/Au pad structure of claim 1, wherein the pad comprises a ball pad.

6. The Ni/Au pad structure of claim 1, wherein the pad comprises a passive pad.

7. The Ni/Au pad structure of claim 1, wherein the pad is located at a terminal of a conductive trace of the substrate.

8. The Ni/Au pad structure of claim 1, wherein the Ni/Au layer is formed at a central portion of the connecting surface.

9. The Ni/Au pad structure of claim 1, wherein the Ni/Au layer is free of being in contact with the solder mask layer.

10. A fabrication method of a Ni/Au pad structure of a semiconductor package, comprising the steps of:
preparing a core layer;
forming a conductive trace layer on the core layer;
forming a photoresist layer to define a predetermined plating region on the conductive trace layer;
forming a Ni/Au layer on the predetermined plating region;
removing the photoresist layer;
patterning the conductive trace layer to form at least one pad at a position of the Ni/Au layer, wherein an area of the pad is larger than an area of the Ni/Au layer; and
applying a solder mask layer and forming at least one opening in the solder mask layer to expose the pad, wherein an area of the opening is larger than the area of the Ni/Au layer.

11. The fabrication method of claim 10, wherein the area of the opening is equal to the area of the pad.

12. The fabrication method of claim 10, wherein the area of the opening is smaller than the area of the pad.

13. The fabrication method of claim 10, wherein the area of the opening is larger than the area of the pad.

14. The fabrication method of claim 10, wherein the pad comprises a ball pad.

15. The fabrication method of claim 10, wherein the pad comprises a passive pad.

16. The fabrication method of claim 10, wherein the Ni/Au layer is formed at a central portion of the pad.

17. The fabrication method of claim 10, wherein the Ni/Au layer is free of being in contact with the solder mask layer.

18. A fabrication method of a Ni/Au pad structure of a semiconductor package, comprising the steps of:
preparing a core layer;
forming a conductive trace layer on the core layer;
patterning the conductive trace layer to form at least one pad of the conductive trace layer;
applying a conductive layer;
forming a photoresist layer to define a predetermined plating region on the pad, wherein an area of the predetermined plating region is smaller than an area of the pad;
forming a Ni/Au layer on the predetermined plating region;
removing the photoresist layer and etching away the conductive layer; and
applying a solder mask layer and forming at least one opening in the solder mask layer to expose the pad, wherein an area of the opening is larger than an area of the Ni/Au layer.

19. The fabrication method of claim 18, wherein the area of the opening is equal to the area of the pad.

20. The fabrication method of claim 18, wherein the area of the opening is smaller than the area of the pad.

21. The fabrication method of claim 18, wherein the area of the opening is larger than the area of the pad.

22. The fabrication method of claim 18, wherein the pad comprises a ball pad.

23. The fabrication method of claim 18, wherein the pad comprises a passive pad.

24. The fabrication method of claim 18, wherein the predetermined plating region is formed at a central portion of the pad.

25. The fabrication method of claim 18, wherein the Ni/Au layer is free of being in contact with the solder mask layer.
